(19) United States
(12) Patent Application Publication
(10) Pub. No.: US 2005/0285146 A1
(43) Pub. Date: Dec. 29, 2005

(54) Semiconductor device, manufacturing method of the semiconductor device, and design method of the semiconductor device

(76) Inventor: Mitsutaka Iwasaki, Kanagawa (JP)

Correspondence Address: DICKSTEIN SHAPIRO MORIN & OSHINSKY LLP, 2101 L Street, NW, Washington, DC, 20037, US

(21) Appl. No.: 11/154,631

(22) Filed: Jun. 17, 2005

(30) Foreign Application Priority Data
Jun. 24, 2004 (JP) 2004-186527

(51) Int. Cl. H01L 27/10; H01L 29/739

(52) U.S. Cl. 257/202

(57) ABSTRACT

A semiconductor device includes a plurality of primitive cells having multilayer wiring structures and formed on a substrate. The primitive cell includes a functional cell having a logic circuit and a wiring cell. The wiring cell includes a wiring part electrically connecting a plurality of the functional cells. The wiring part is a top layer connection wiring formed by a top layer wiring of the multilayer wiring structure.

### BACKGROUND OF THE INVENTION

1. Field of the Invention

The present invention relates to semiconductor devices, manufacturing methods of semiconductor devices, and design methods of semiconductor devices, and more specifically, to a semiconductor device having a multilayer wiring structure, a manufacturing method of the semiconductor device, and a design method of the semiconductor device.

2. Description of the Related Art

A circuit design support tool of a semiconductor device such as an automatic arrangement wiring tool may be used for forming an integrated circuit of the semiconductor device. By the automatic arrangement wiring tool, an arrangement of a primitive cell (“cell” or “standard cell”) which is a minimum unit circuit of a semiconductor integrated circuit is determined on a substrate, and a connection circuit connecting the primitive cells is designed and determined based on a net list where signal connection information between the primitive cells are described. Such an automatic arrangement wiring tool may be used for a random logic part of the integrated circuit of the semiconductor device.

FIG. 1 is a schematic view showing an example of a circuit diagram including a primitive cell and a net list of a related art example.

Referring to FIG. 1, a circuit C1 of a semiconductor device has, for example, primitive cells P1 through P3. The circuit C1 also has connection wirings N1 through N6 connecting to the primitive cells P1 through P3. More specifically, the connection wirings N1 through N6 are arranged based on a net list NL1. For example, the primitive cells P1 and P2 are connected to each other by the connection wiring N4. The primitive cells P3 and P2 are connected by the connection wiring N6. The connection wirings N1 and N2 are connected to the primitive cell P1, the connection wiring N5 is connected to the primitive cell P2, and the connection wiring N3 is connected to the primitive cell P3, so as to further connect to primitive cells (not shown in FIG. 1). Based on such a circuit diagram and the net list, details of an arrangement of the primitive cells and a structure of the connection wiring are determined by the automatic arrangement wiring tool, following the algorithm of the automatic arrangement wiring tool.

FIG. 2 is a schematic plan view of a semiconductor device formed by the automatic arrangement wiring tool based on the circuit diagram and the net list shown in FIG. 1. Primitive cells p1 through p3 in FIG. 2 correspond to the primitive cells P1 through P3 in FIG. 1. Similarly, connection wiring n1 through n6 in FIG. 2 corresponds to the wiring connections N1 through N6 in FIG. 1.

Referring to FIG. 2, the semiconductor shown in FIG. 2 has a structure where plural primitive cells are arranged on a substrate S1. The semiconductor device includes a cell line 11 formed by an arrangement of plural primitive cells in a substantially straight line and a cell line 12 formed by an arrangement of plural primitive cells in a substantially straight line state and arranged in parallel with the cell line 11. An area d1 where a wiring of an electric power source line and a wiring of a ground line are formed is provided between the cell lines 11 and 12. The primitive cells p2 and p3 are included in the cell line 11. The primitive cell p2 is included in the cell line 12.

The semiconductor device shown in FIG. 2 has a multilayer wiring structure. The primitive cells formed in the cell lines 11 and 12 and the connection wiring connecting to the primitive cells are formed in one or plural layers of the multilayer wiring. For example, a wiring m1 represents a wiring situated at a lowest layer, namely first layer. A wiring m2 represents a wiring situated at a second layer. A wiring m3 represents a wiring situated at a third layer. A wiring m4 represents a wiring situated at a fourth layer. A wiring m5 represents a wiring situated at a fifth layer. In this case, since the semiconductor device has a multilayer wiring structure formed by five layers, the wiring m5 is a top layer wiring.

For example, the connection wiring n6 which connects the primitive cells p2 and p3 has a structure formed by the wirings m2 and m3. The connection wiring n6 is formed as follows in a direction from the primitive cell p2 to the primitive cell p3. A pin formed in the primitive cell p2 is connected to the wiring m3. The wiring m3 is connected to the wiring m2 via a contact. The wiring m2 is connected to the wiring m3 via a contact. The wiring m3 is connected to the wiring m2 via a contact. The wiring m2 is connected to a pin formed in the primitive cell p3.

Similarly, the connection wiring n4 which connects the primitive cells p1 and p2 has a structure formed by the wirings m2 and m3. The connection wiring n4 is formed as follows in a direction from the primitive cell p1 to the primitive cell p2. A pin formed in the primitive cell p1 is connected to the wiring m2. The wiring m2 is connected to the wiring m3 via a contact. The wiring m3 is connected to the wiring m2 via a contact. The wiring m2 is connected to a pin formed in the primitive cell p2.

The connection wiring n1 includes the wirings m2 and m3. The connection wiring n2 includes the wirings m3 and m4. The connection wiring n3 includes the wiring m2. The connection wiring n5 includes the wiring m1.

In such a semiconductor device having a multilayer wiring structure, if a defect in the semiconductor device is found by implementing an operations test using an LSI tester or a substrate for evaluating, for example, the defect may be resolved by correcting the connection wiring. In this case, the formed wiring is cut so that another wiring is formed, and thereby a connection is remade. FIB (Focused Ion Beam) processing using a FIB may be used for cutting the wiring, for example.

FIG. 3 is a circuit diagram showing correction processing for the circuit C1 shown in FIG. 1. In FIG. 3, parts that are the same as the parts shown in FIG. 1 are given the same reference numerals, and explanation thereof is omitted. Referring to FIG. 3, when the correction shown in FIG. 3 is made, for example, a part of a connection wiring N6 is cut at a cutting point A1 and a part of a connection wiring N5 is cut at a cutting point A2 by the FIB processing. Then, a new connection wiring L1 is formed so as to be connected to a connection point B1 of the connection wiring N6 and a connection point B2 of the connection wiring N5.

However, in a case where the correction is made by the FIB processing, in the semiconductor device having the multilayer wiring structure, other wiring is formed on the wiring that is a subject of the correction so that the wiring of the subject of the correction may be covered and therefore the FIB processing may be difficult.

FIG. 4 is a partially enlarged view of the semiconductor device shown in FIG. 3. In FIG. 4, parts that are the same as the parts shown in FIG. 2 are given the same reference numerals, and explanation thereof is omitted. In FIG. 3, although the connection wirings which connect the primitive cells are shown, other wirings are omitted. However, as shown in FIG. 4, various multi wirings are actually formed in the primitive cells. For example, the connection wiring n5, with the necessity for being cut by the FIB processing is the wiring m1 formed in the first layer. The wirings m2 through m4 are formed so as to cover the connection wiring n5. Hence, it may be difficult to perform the FIB processing.

Japanese Patent Application Publication No. 2001-264723 discloses a method whereby a dummy wiring is provided on all of the primitive cells in advance and the dummy wiring is used for the corrected wiring in order to shorten the wiring formed by the correction in a case where the circuit is corrected. However, this Japanese Patent Application Publication does not disclose a detailed method for solving a problem where the wiring being a subject of the correction is covered with the upper layer wiring when the subject wiring is cut by the FIB processing so that it is difficult to implement the FIB processing. In addition, a part being cut by the FIB processing may be covered with the dummy wiring. Furthermore, a thickness sufficient for forming the dummy wiring is necessary so that the thickness of the semiconductor device may be large.

Japanese Patent Application Publication No. 2002-164510 discloses a method whereby a connection is performed via a dummy cell formed in advance and a top layer wiring formed to surround the cell is used for the wiring of the cell that is a subject of the correction and the dummy cell when the circuit is corrected.

However, this Japanese Patent Application Publication does not disclose a detailed method for solving a problem where the wiring being a subject of the correction is covered with the upper layer wiring when the subject wiring is cut by the FIB processing so that it is difficult to implement the FIB processing. In addition, it is necessary to make a space forming the top layer wiring surrounding the cell and therefore the space for forming necessary wiring may be narrowed.

### SUMMARY OF THE INVENTION

Accordingly, it is a general object of the present invention to provide a novel and useful semiconductor device, manufacturing method of the semiconductor device, and design method of the semiconductor device in which one or more of the problems described above are eliminated.

Another and more specific object of the present invention is to provide a semiconductor device, manufacturing method of the semiconductor device, and design method of the semiconductor device whereby wiring correction including cutting of a wiring can be easily performed.

The above-mentioned object of the present invention is achieved by a semiconductor device, including:

a plurality of primitive cells having multilayer wiring structures and formed on a substrate;

wherein the primitive cell includes a functional cell having a logic circuit and a wiring cell,

the wiring cell includes a wiring part electrically connecting a plurality of the functional cells, and

the wiring part is a top layer connection wiring formed by a top layer wiring of the multilayer wiring structure.

According to this invention, since the functional cell is connected via the top layer connection wiring, it is possible to easily correct the circuit of the semiconductor device.

A lower layer wiring may be formed in a lower layer of the wiring cell lower than the top layer connection wiring.

According to this invention, it is possible to effectively use the wiring cell as a wiring area.

The wiring cell may be connected from the lower layer wiring to the top layer connection wiring.

According to this invention, it is possible to connect to the functional cell and the wiring cell by using the multilayer wiring structure.

The lower layer wiring may be formed in the functional cell, and the functional cell may be connected to the top layer connection wiring via the lower layer wiring.

According to this invention, it is possible to connect to the functional cell and the wiring cell by using the multilayer wiring structure.

The functional cell and the wiring cell may be arranged in a straight line so as to form a primitive cell line, and a plurality of the primitive cells may be formed in parallel.

According to this invention, it is possible to form the semiconductor device having high integration and a microstructure.

A wiring structure including the wiring part may be formed in the wiring cell.

According to this invention, it is possible to simplify a structure of the wiring cell.

The above-discussed object of the present invention is also achieved by a manufacturing method of a semiconductor device having a multilayer wiring structure, including the steps of:

arranging primitive cells wherein a circuit is defined and designing a connection circuit connecting the primitive cells; and

forming the primitive cells on a substrate based on the design;

wherein the primitive cell includes a functional cell having a logic circuit and a wiring cell having a wiring part electrically connecting a plurality of the functional cells, and

the wiring part includes a top layer connection wiring formed by a top layer wiring of the multilayer wiring structure.

According to the above-mentioned manufacturing method of the semiconductor device, since the functional cell is connected via the top layer connection wiring, it is possible to manufacture a semiconductor device wherein the circuit of the semiconductor device can be easily corrected.

An input pin and an output pin of the wiring cell may be formed on the top layer connection wiring.

According to this invention, the functional cell is connected via the top layer connection wiring.

The connection circuit may include a circuit connecting a plurality of the functional cells via the wiring cell.

According to this invention, a connection circuit can be formed so that the functional cell is connected via the wiring cell by the automatic arrangement wiring tool.

The wiring part defined in the wiring cell may include only the top layer wiring.

According to this invention, it is possible to simplify a structure of the wiring cell.

A lower layer wiring formed in a layer lower than the top layer wiring may be defined in the functional cell.

According to this invention, it is possible to design a connection wiring from a lowest layer wiring to the top connection wiring by the automatic arrangement wiring tool.

The connection circuit may include a circuit connecting the lower layer wiring formed in the functional cell and the top layer connection wiring.

According to this invention, it is possible to design a connection wiring from a lowest layer wiring to the top connection wiring by the automatic arrangement wiring tool.

The manufacturing method of the semiconductor device may further include the steps of:

testing an operation of an integrated circuit formed by the primitive cells; and

correcting a circuit of the primitive cell, corresponding to the result of testing the operation.

According to this invention, it is possible to easily correct the circuit of the semiconductor device so that the cost for correcting the semiconductor device can be reduced.

The top layer connection wiring may be cut so that the circuit is corrected.

According to this invention, it is possible to easily correct the top connection wiring.

The top layer connection wiring may be cut by a focused ion beam.

According to this invention, it is possible to easily correct the top connection wiring.

Plural functional cells may be electrically connected via the top layer connection wiring. It is possible to easily correct the circuit of the semiconductor device.

The functional cell and the wiring cell may be arranged in a straight line so as to form a primitive cell line, and a plurality of the primitive cells may be formed in parallel.

According to this invention, it is possible to form the semiconductor device having high integration and a microstructure.

The above-discussed object of the present invention is achieved by a design method of a semiconductor device having a multilayer wiring structure, including the steps of:

arranging primitive cells wherein a circuit is defined and designing a connection circuit connecting the primitive cells; and

forming the primitive cells on a substrate based on the design;

wherein the primitive cell includes a functional cell having a logic circuit and a wiring cell having a wiring part electrically connecting a plurality of the functional cells, and

the wiring part includes a top layer connection wiring formed by a top layer wiring of the multilayer wiring structure.

According to the above-mentioned design method of the semiconductor device, since the functional cell is connected via the top layer connection wiring, it is possible to form a semiconductor device wherein the circuit of the semiconductor device can be easily corrected.

An input pin and an output pin of the wiring cell may be formed on the top layer connection wiring.

According to this invention, the functional cell is connected via the top layer connection wiring.

The connection circuit may include a circuit connecting a plurality of the functional cells via the wiring cell.

According to this invention, a connection circuit can be formed so that the functional cell is connected via the wiring cell by the automatic arrangement wiring tool.

The wiring part defined in the wiring cell may include the only top layer wiring.

According to this invention, it is possible to simplify a structure of the wiring cell.

A lower layer wiring formed in a layer lower than the top layer wiring may be defined in the functional cell.

According to this invention, it is possible to design a connection wiring from a lowest layer wiring to the top connection wiring by the automatic arrangement wiring tool.

The connection circuit may include a circuit connecting the lower layer wiring formed in the functional cell and the top layer connection wiring.

According to this invention, it is possible to design a connection wiring from a lowest layer wiring to the top connection wiring by the automatic arrangement wiring tool.

Other objects, features, and advantages of the present invention will become more apparent from the following detailed description when read in conjunction with the accompanying drawings.

### BRIEF DESCRIPTION OF THE DRAWINGS

FIG. 1 is a schematic view showing an example of a circuit diagram including a primitive cell and a net list of a related art semiconductor device;

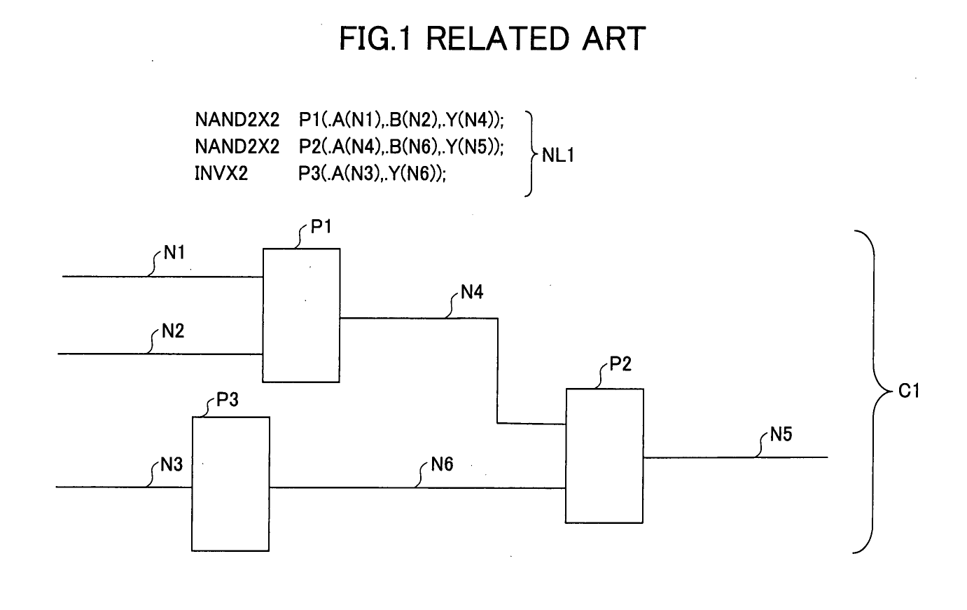

FIG. 2 is a schematic plan view showing an arrangement of the primitive cells and the wiring of the related art semiconductor device;

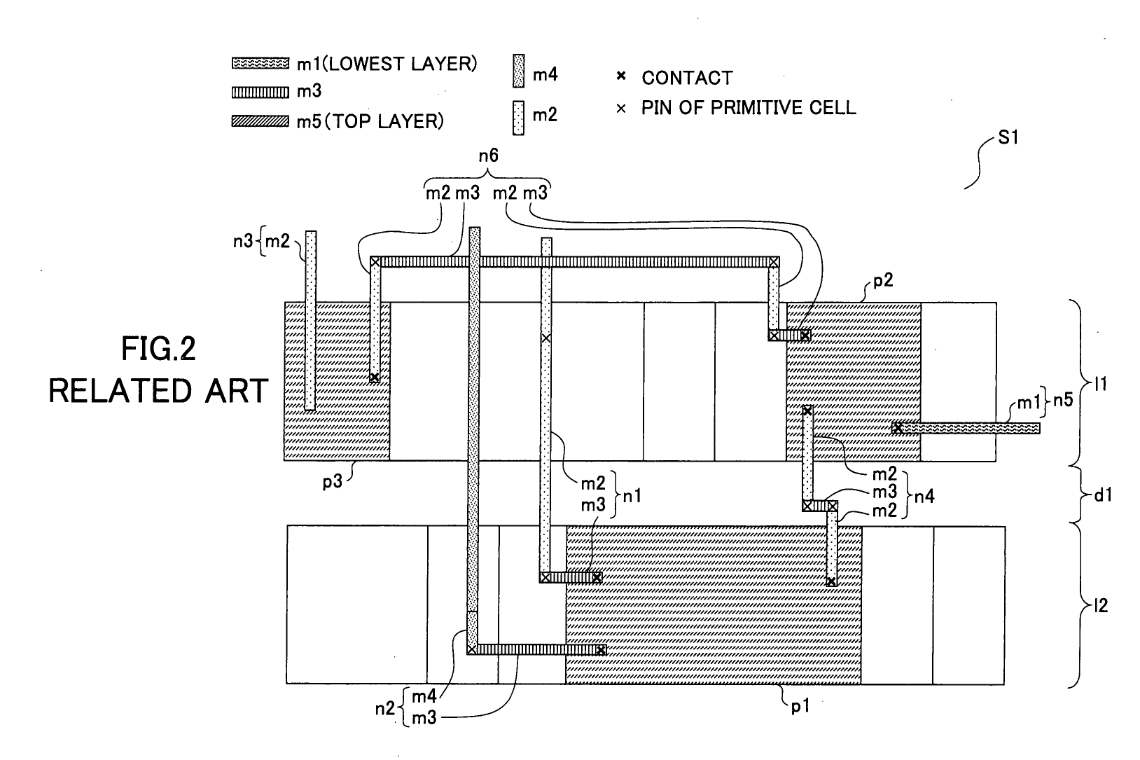

FIG. 3 is a circuit diagram showing correction processing of the related art semiconductor device;

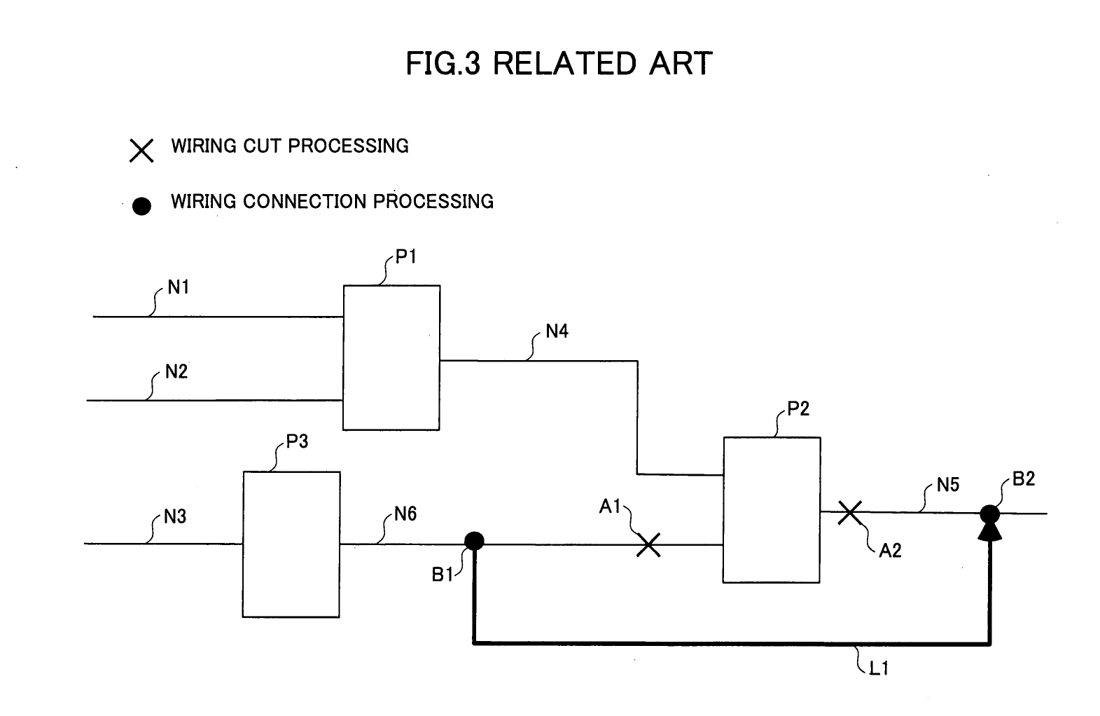

FIG. 4 is a schematic plan view showing details of an arrangement state of the related art semiconductor device;

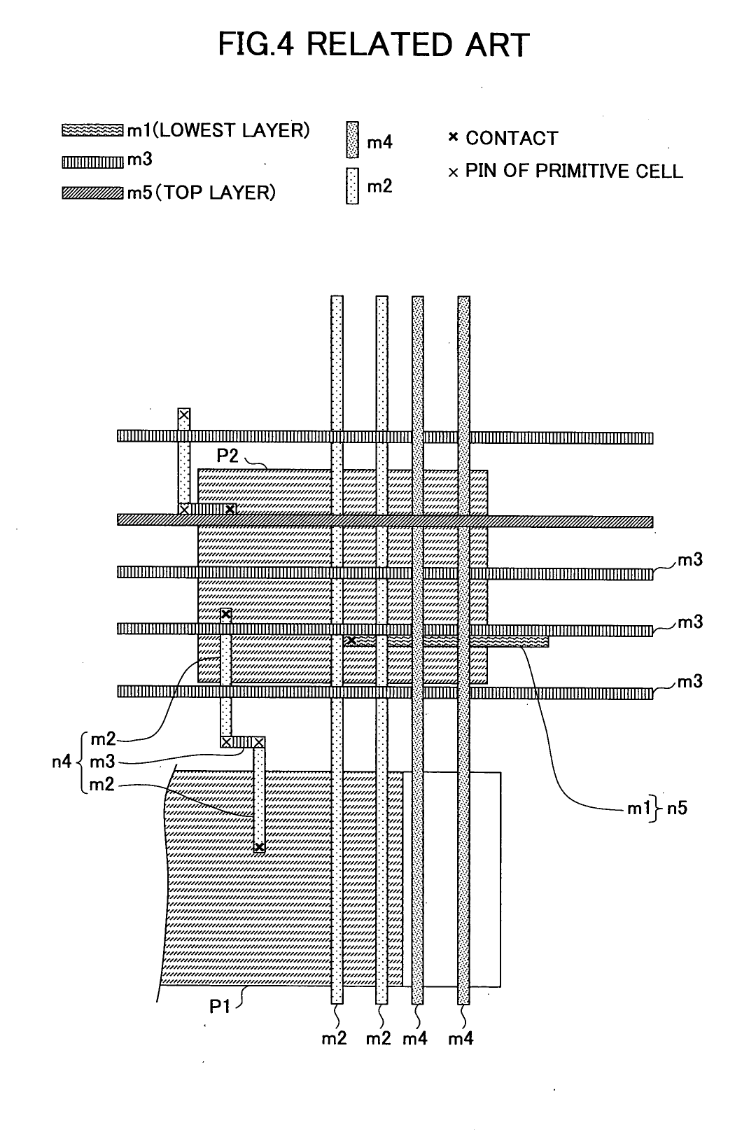

FIG. 5 is a flowchart showing a manufacturing method of a semiconductor device of a first embodiment of the present invention;

FIG. 6 is a schematic plan view of a wiring cell of the first embodiment of the present invention;

FIG. 7 is a schematic plan view of a functional cell of the first embodiment of the present invention;

FIG. 8 is a schematic view showing of a circuit diagram including a primitive cell and a net list of the semiconductor device of the first embodiment of the present invention;

FIG. 9 is a schematic plan view showing an arrangement of the primitive cells and the wiring of the semiconductor device of the first embodiment of the present invention;

FIG. 10 is a circuit diagram showing correction processing of the semiconductor device of the first embodiment of the present invention;

FIG. 11 is a schematic plan view showing correction processing of the semiconductor device of the first embodiment of the present invention, and

FIG. 12 is a schematic plan view showing details of an arrangement state of the semiconductor device of the first embodiment of the present invention.

### DETAILED DESCRIPTION OF THE PREFERED EMBODIMENTS

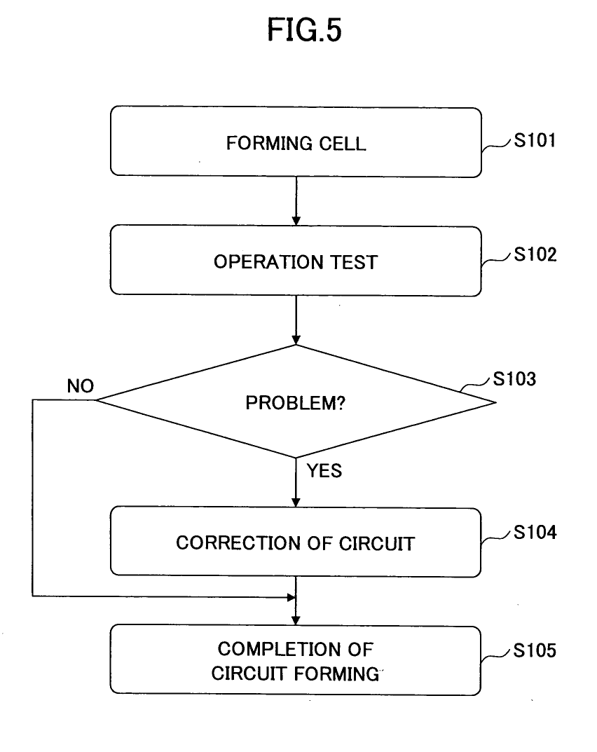

A description of the present invention and details of drawbacks of the related art are now given, with reference to FIG. 5 through FIG. 12, including embodiments of the present invention.

### First Embodiment

A semiconductor device in this embodiment has a multilayer wiring structure. Plural wiring layers, having plural wirings formed in a plane surface situated substantially parallel with a substrate surface where the device is formed are stacked. In the followings, the wiring layer formed in a side nearest to the substrate is described as a lowest layer wiring. The wiring layer formed at the top of the wiring layers stacked on the lowest layer wiring is described as a top layer wiring. For example, the top layer wiring may be covered with a protection layer (passivation layer).

FIG. 5 is a flowchart showing a manufacturing method of the semiconductor device of a first embodiment of the present invention.

Referring to FIG. 5, in step 101, an arrangement of primitive cells wherein a circuit is defined and a connection circuit connecting the primitive cells is designed by using the automatic arrangement wiring tool. Based on the design, the primitive cells are arranged and wired on the semiconductor substrate so that an integrated circuit is formed on the substrate. Details of the design method are discussed below.

Then, in step 102, an operations test of the integrated circuit such as a random logic circuit is performed by using an LSI tester or a substrate for evaluating, for example. Forming of the integrated circuit is completed if no problem is found by the operations test in this step. If a problem is found by the operations test, the integrated circuit is corrected depending on the problem.

Such a correction of the integrated circuit causes cutting of the existing wiring and forming of new wiring. The cutting of the wiring may be performed by the FIP processing. In this case, in the semiconductor device having the multilayer structure, other wiring is formed on the wiring which is a subject of the correction so that the wiring which is the subject of the correction is covered and therefore it may be difficult to perform the FIP processing.

Because of this, in this embodiment, plural primitive cells formed on the substrate are each formed by plural functional cells having logic circuits and wiring cells electrically connecting the functional cells. The wiring cell includes the top layer connection wiring formed by a top layer wiring of the multilayer structure. Therefore, in a case where the FIB processing can be performed for correcting the circuit, by cutting the top layer connection wiring formed by the top layer wiring of the wiring cell, the circuit can be easily corrected.

Furthermore, it is possible to easily observe a signal wave form of the circuit of the semiconductor device when the signal wave form is checked by using an EB tester. This is because the EB tester recognizes a change of a magnetic field generated by an electric current flowing in the wiring and therefore the magnetic field is stronger and easily detectable as a measurement point is situated nearer to the wiring which is a subject of the measurement. In this embodiment, it is possible to easily observe the signal wave form at the top layer connection wiring by the EB tester.

Next, detailed examples of the wiring cell are discussed.

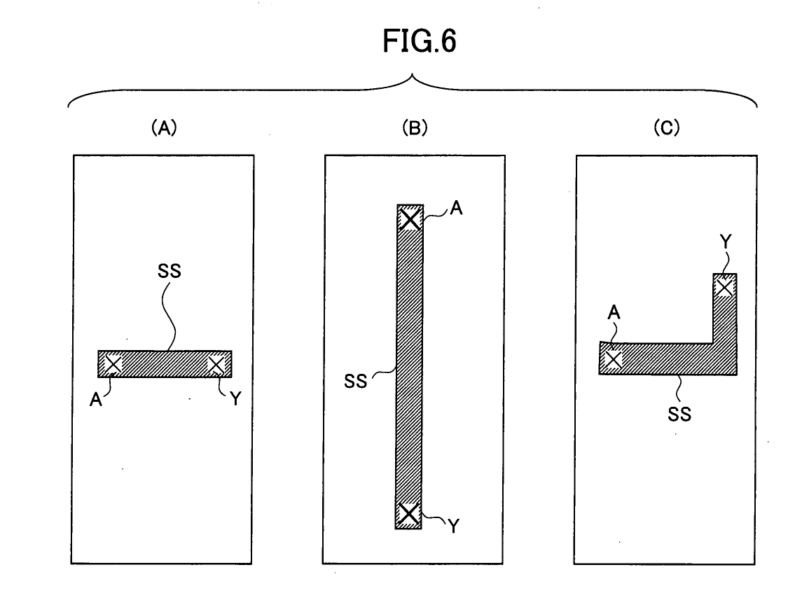

FIG. 6(A) through FIG. 6(C) are schematic plan views of a structure of the wiring cell of the first embodiment. Referring to FIG. 6(A) through FIG. 6(C), the wiring cell is defined on the design so as to have a top layer connection wiring SS formed by the top layer wiring in the multilayer wiring structure of the semiconductor integrated circuit. In addition, an input pin A and an output pin Y of the wiring cell are defined so as to be formed at end parts of the top layer connection wiring.

If the wiring defined to the wiring cell is formed by the only top layer wiring, the top layer connection wiring SS in this case, for example, the functional cell is securely connected via the top layer wiring and the structure of the wiring cell is made simple. However, the lowest layer wiring may be defined. For example, in a case where the lowest layer wiring is defined at the wiring cell, considering positions of the input and output pins, it is preferable to set a position of the pin so that the functional cell is securely connected via the top layer wiring (top layer connection wiring SS).

In addition, a definition on the design can be made so that the top layer connection wiring SS has various configurations. For example, as shown in FIG. 6(A), the top layer connection wiring SS may be substantially perpendicular to a longitudinal direction of the wiring cell. As shown in FIG. 6(B), the top layer connection wiring SS may be substantially parallel with the longitudinal direction of the wiring cell. As shown in FIG. 6(B), the top layer connection wiring SS may have a substantially L-shaped configuration.

The functional cell used in this embodiment has a function and a structure substantially the same as a standard cell which is conventionally used. The functional cell includes a logic circuit such as a transistor. In this embodiment, a cell which is a subject to be connected by the wiring cell in the primitive cells is used as the functional cell.

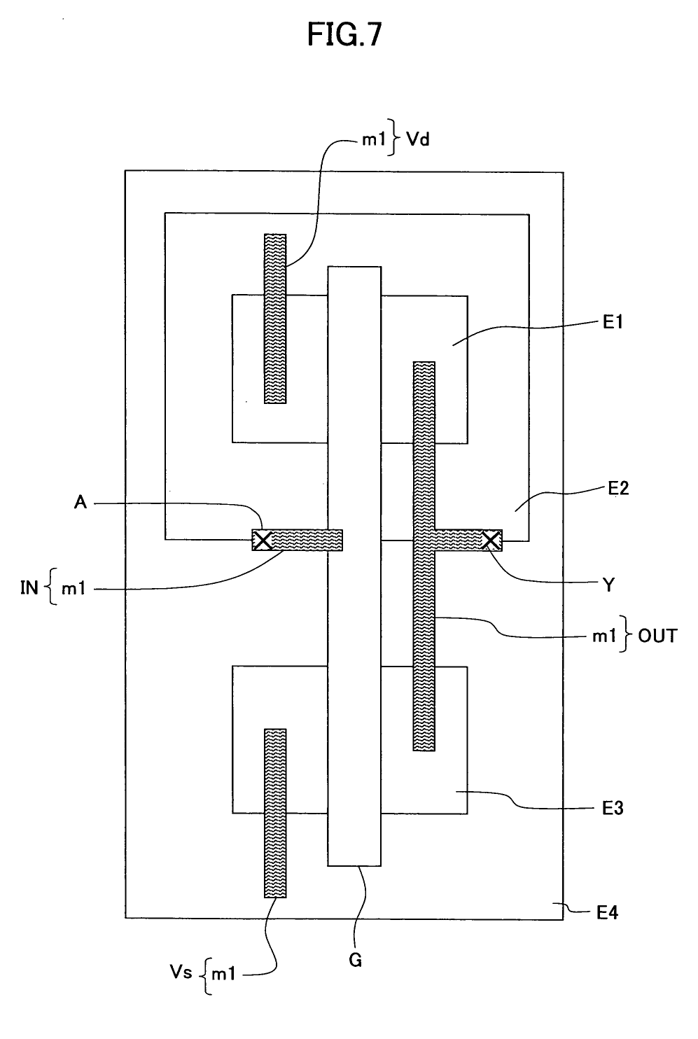

FIG. 7 is a plan view showing an example of the structure of the functional cell. The functional cell is, on the design, defined as shown in FIG. 7.

Referring to FIG. 7, the functional cell shown in FIG. 7 has an inverter circuit having two transistors. The functional cell has, for example, a diffusion area E1 of high density P type impurities, a diffusion area E3 of high density N type impurities, a diffusion area E2 of low density N type impurities, and a diffusion area E4 of low density P type impurities. A gate electrode G is formed so as to cross from the diffusion area E1 to the diffusion area E3. A wiring IN formed by the lowest layer wiring ml and connected to the gate electrode G is formed. A source electrode and a drain electrode (not shown in FIG. 7) are formed one in each of the diffusion areas E1 and E3. Wirings formed by the wiring ml which is the lowest layer wiring are formed as follows so as to be connected to the source and drain electrodes. That is, a wiring OUT connecting the diffusion areas E1 and E3, a wiring Vd connecting the diffusion area E1 and an electric power source voltage line, and a wiring Vs connecting the diffusion area E3 and a ground line are formed as shown in FIG. 7.

An input pin A is provided in the wiring IN and an output pin Y is provided in the wiring OUT. Such a functional cell is not limited to the inverter but may have other logic circuit.

Conventionally, in a case where such a functional cell (standard cell) is arranged especially a random logic part, the structure of a connected wiring is often determined by the automatic arrangement wiring tool. Because of this, the wiring connecting the cell becomes complicated in the multilayer structure. Particularly, in a case where the circuit is corrected, the wiring which is a subject of the correction is covered with a wiring of the upper layer. This causes reduced visibility in the case of the FIB processing and increased difficulty of spattering and wiring forming after the FIB processing. This problem is serious for a semiconductor device wherein the wiring is micro-structured and the circuit is highly integrated.

Such problems are solved and plural functional cells are connected via the wiring cell in this embodiment. Since the wiring cell has a top layer connecting wiring which is a top layer wiring of a multilayer wiring structure and the functional cell is connected to the wiring cell via the top layer connection wiring, it is possible to perform to the circuit correction by the correction of the top layer wiring. Because of this, the upper layer of the wiring which is a subject of the correction is not covered with other wiring at the time of the FIB processing and therefore it is possible to achieve a high processing ability. More specifically, it is easy to find the wiring which is a subject of the processing and it is possible to easily implement the cutting of the wiring by spattering in a short period of time in the case of the FIB processing.

In a highly efficient semiconductor device wherein the wiring is micro-structured and the circuit is highly integrated, it is possible to obtain high visibility of the wiring which is a subject of the wiring and a high processing ability in the case of the circuit correction.

Next, a detailed example in a case where a semiconductor device is formed by using the above-discussed wiring cell and functional cell is discussed.

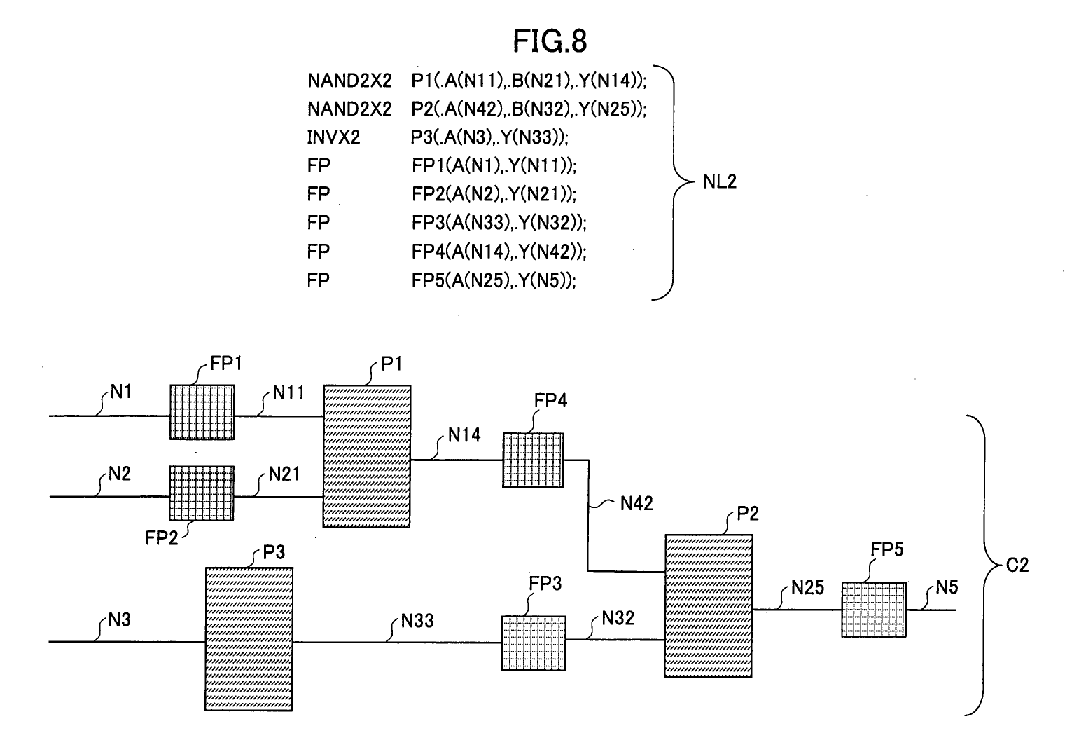

FIG. 8 is a schematic view showing a circuit diagram including a primitive cell and a net list of the semiconductor device of this embodiment of the present invention.

Referring to FIG. 8, a circuit C2 of the semiconductor device has plural primitive cells. The primitive cells are formed by functional cells P1 through P3 each having a logic circuit and wiring cells FP1 through FP5 having wiring parts which electrically connect the functional cells. That is, in the circuit diagram, the wiring cell is connected to the connection part of plural functional cells. For example, the functional cells P1 and P2 are connected via the wiring cell FP4. The functional cell P1 and the wiring cell FP4 are connected by the connection wiring N14. The wiring cell FP4 and the functional cell P2 are connected by the connection wiring N42. Similarly, the functional cells P2 and P3 are connected via the wiring cell FP3. The functional cell P2 and the wiring cell FP3 are connected by the connection wiring N32. The wiring cell FP3 and the functional cell P3 are connected by the connection wiring N33.

The wiring cell FP1 is connected to the functional cell P1 via the connection wiring N11 and the wiring cell FP2 is connected to the functional cell P1 via the connection wiring N21. The wiring cells FP1 and FP2 are connected to other functional cells (not shown in FIG. 8) via the connection wirings N1 and N2, respectively.

Similarly, the wiring cell FP5 is connected to the functional cell P2 via the connection wiring N25. The wiring cell FP5 is connected to other functional cells (not shown in FIG. 8) via the connection wiring N5.

The connection wiring N3 connecting the functional cell P3 may be connected to other functional cells via a wiring cell.

The above-mentioned connection wiring is arranged and wired based on the net list NL2. Based on such a circuit diagram and the net list, an arrangement of the primitive cells and a structure of the connection wiring are determined by the automatic arrangement wiring tool, following the algorithm of the automatic arrangement wiring tool.

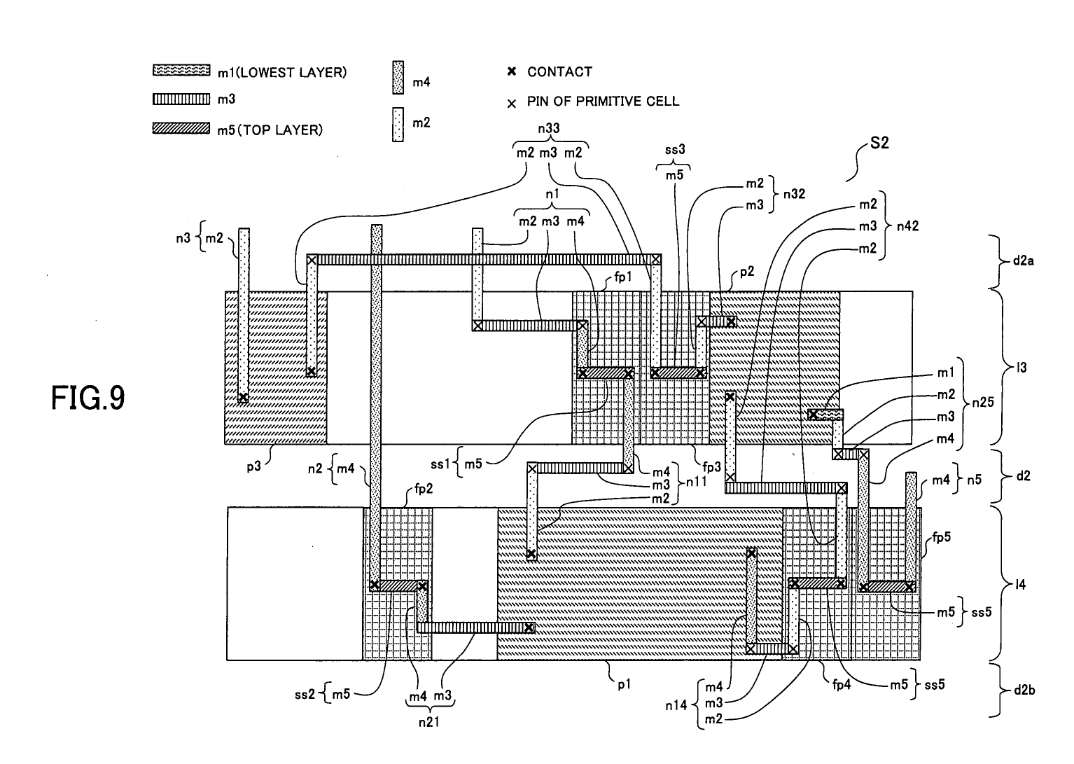

FIG. 9 is a schematic plan view showing an arrangement of the primitive cells and the wiring of the semiconductor device based on the circuit diagram and the net list shown in FIG. 8. The functional cells p1 through p3 shown in FIG. 9 correspond to the functional cells P1 through P3 shown in FIG. 8. Connection wirings n1 through n3, n5, n11, n21, n14 n42, n25, n32 and n33 correspond to the connection wirings N1 through N3, N5, N11, N21, N14 N42, N25, N32 and N33.

Referring to FIG. 9, the semiconductor device shown in FIG. 9 has a structure where primitive cells formed by plural functional and wiring cells are arranged on the substrate S2. The semiconductor device includes a cell line 13 formed by arrangement of plural primitive cells in a substantially straight line and a cell line 14 formed by arrangement of plural primitive cells in a substantially straight line and formed in parallel with the cell line 13. An area d2 where a wiring of the electric power source or the wiring of the ground line are formed is provided between the cell lines 13 and 14. An area d2a is formed at a side facing the area d2 via the cell line 13. An area d2b is formed at a side facing the area d2 via the cell line 14. The functional cells p2 and p3 and the wiring cells fp1 and fp3 are included in the cell line 13.

The functional cells p2 and p3 and the wiring cells fp1 and fp3 are included in the cell line 13. The functional cell p1 and the wiring cells fp2, fp4, and fp5 are included in the cell line 14. Therefore, for example, the top layer wiring for connecting the functional cell is efficiently received in the cell line so that a space for the wiring can be saved.

The semiconductor device shown in FIG. 9 has a multilayer structure. The primitive cells formed in the cell lines 13 and 14 and the connection wiring which connects the primitive cells are formed in one or plural layers of the multilayer wiring.

A wiring m1 represents a wiring situated at a lowest layer, namely first layer. A wiring m2 represents a wiring situated at a second layer. A wiring m3 represents a wiring situated at a third layer. A wiring m4 represents a wiring situated at a fourth layer. A wiring m5 represents a wiring situated at a fifth layer. In this case, since the semiconductor device has a multilayer wiring structure formed by five layers, the wiring m5 is a top layer wiring.

The wiring cell in this embodiment has, at least, a top layer connection wiring formed by a top layer wiring of the multilayer wiring structure. Plural functional cells are connected via the top layer connection wiring. For example, the wiring cells fp1 through fp5 have top layer connection wirings ss1 through ss5 formed by the top layer wirings m5. Plural functional cells are connected via these top layer connection wirings.

For example, the connection wiring n14 which connects the functional cell p1 and the wiring cell fp4 has a structure formed by the wirings m2, m3 and m4. The connection wiring n14 is formed as follows in a direction from the functional cell p1 to the wiring cell fp4. A pin formed in the functional cell p1 is connected to the wiring m4. The wiring m4 is connected to the wiring m3 via a contact. The wiring m3 is formed from the functional cell p1 to the wiring cell fp4. The wiring m3 is connected to the wiring m2 at a side of the wiring cell fp4 via a contact. The wiring m2 is connected to the top layer connection wiring ss4 formed by the wiring m5 which is a top layer wiring formed in the wiring cell fp4 via a pin.

The connection wiring n42 which connects the wiring cell fp4 and the wiring cell p2 has a structure formed by the wirings m2 and m3. The connection wiring n42 is formed as follows from the wiring cell fp4 to the functional cell p2. A pin formed in the top layer connection wiring ss4 is connected to the wiring m2 via a contact. The wiring m2 is formed from the wiring cell fp4 to the area d2. The wiring m2 is connected to the wiring m3 in the area d2 via a contact. The wiring m3 is connected to the wiring m2 via a contact. The wiring m2 is formed from the area d2 to the functional cell p2. The wiring m2 is connected to the logic circuit such as the inverter of the functional cell p2 via a contact.

The connection wiring n32 which connects the wiring cell fp3 and the functional cell p2 has a structure formed by the wirings m2 and m3. The connection wiring n32 is formed as follows from the functional cell p2 to the wiring cell fp3. A pin formed in the functional cell p2 is connected to the wiring m3. The wiring m3 is formed from the functional cell p2 to the wiring cell fp3. The wiring m3 is connected to the wiring m2 at the side of the wiring cell fp3 via a contact. The wiring m2 is connected to the top layer connection wiring ss3 formed by the wiring m5 which is a top layer wiring formed in the wiring cell fp3, via a pin.

The connection wiring n33 which connects the wiring cell fp3 and the functional cell p3 has a structure formed by the wirings m2 and m3. The connection wiring n33 is formed as follows from the wiring cell fp3 to the functional cell p3. A pin formed in the top layer connection wiring ss3 is connected to the wiring m2 via a contact. The wiring m2 is formed from the wiring cell fp4 to the area d2a. The wiring m2 is connected to the wiring m3 in the area d2a via a contact. The wiring m3 is connected to the wiring m2 via a contact. The wiring m2 is formed from the area d2a to the functional cell p3. The wiring m2 is connected to the logic circuit such as the inverter of the functional cell p3 via a pin.

Thus, in this embodiment, the functional cell is connected via the top connection wiring of the wiring cell.

The functional cell p1 and the top layer connection wiring ss1 of the wiring cell fp1 are connected by the connection wiring n11 formed by the wirings m2, m3 and m4. The top layer connection wiring ss1 is connected to other functional cells (not shown) by the connection wiring n1 formed by the wirings m2, m3 and m4.

The functional cell p1 and the top layer connection wiring ss2 of the wiring cell fp2 are connected by the connection wiring n21 formed by the wirings m3 and m4. The top layer connection wiring ss2 is connected to other functional cells (not shown) by the connection wiring n2 formed by the wirings m4.

Similarly, the functional cell p2 and the top layer connection wiring ss5 of the wiring cell fp5 are connected by the connection wiring n25 formed by the wirings m1, m2, m3 and m4. The top layer connection wiring ss5 is connected to other functional cells (not shown) by the connection wiring n5 formed by the wirings m4.

Although the connection wiring n3 formed by the wiring m2 and connecting the functional cell p3 is connected to other functional cells (not shown), the connection wiring n3 may be connected via a wiring cell having the top layer connection wiring as described above.

Although the top layer connection wiring of the wiring cell is formed by the wiring of the top layer of the multilayer wiring structure, the logic circuit of the functional cell has, for example, a transistor and is generally formed in the lowest layer of the substrate. Because of this, the connection wiring which connects the functional cell and the wiring cell is usually connected from the lower layer wiring to the upper layer wiring or from the upper layer wiring to the lower layer wiring.

Therefore, the wiring cell includes the lower layer wiring of the top layer connection wiring formed by the top layer wiring. The wiring cell is also connected from the lower layer wiring to the top layer connection wiring or from the top layer connection wiring to the lower layer wiring. The wiring cell includes a structure where a wiring connecting a wiring having a different layer, such as a via wiring, is formed. A structure where the input pin and output pin are formed at both ends of the top layer connection wiring and connected to the lower layer wiring via a contact is different from a typical structure of the wiring cell.

The lower layer wiring formed in the wiring cell is not designed in advance when the wiring cell is defined but is inevitably designed by the automatic arrangement wiring tool to connect the functional cells wherein the lower layer is defined after the wiring cell formed by only top layer connection wiring is defined.

Thus, in this embodiment, a wiring path to which the functional cell is connected has a structure having at least the top layer wiring. Therefore, the circuit can be easily corrected by correcting the top layer connection wiring formed by the top layer wiring (wiring m5 in this embodiment). An example of the correction of the circuit is discussed as follows.

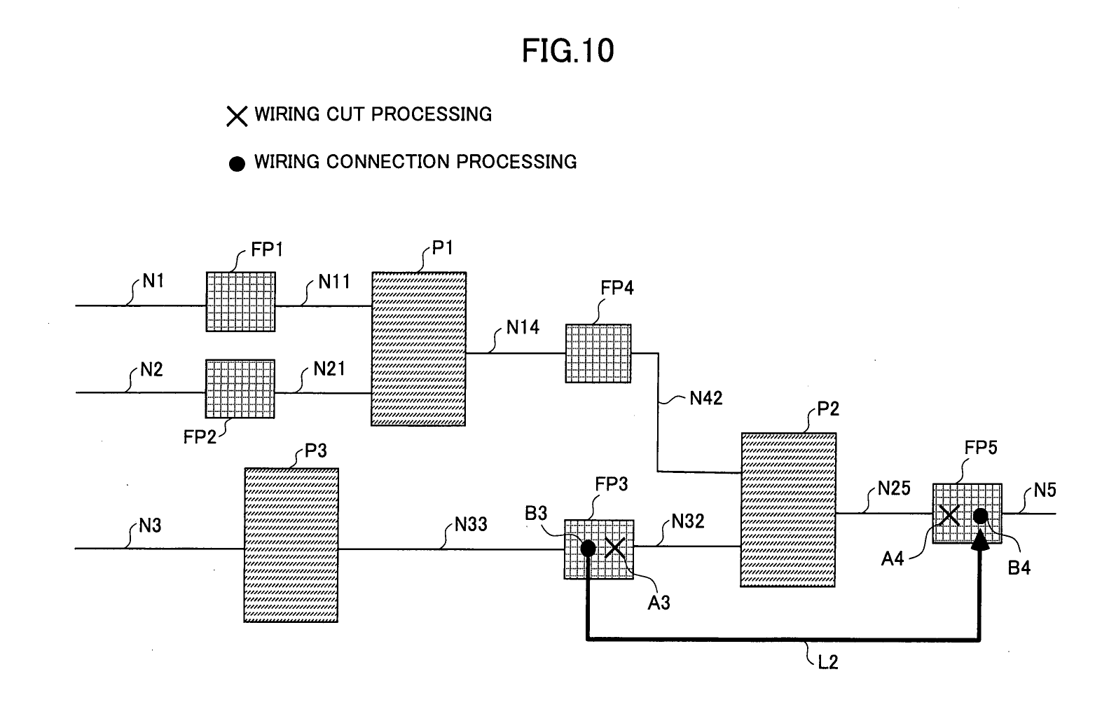

FIG. 10 is a circuit diagram showing an example when the circuit C2 shown in FIG. 8 is corrected. In FIG. 10, parts that are the same as the parts already discussed above are given the same reference numerals, and explanation thereof is omitted. Referring to FIG. 10, when the correction is done as shown in FIG. 10, for example, parts of the top layer connection wiring of the wiring cells FP3 and FP5 are cut at the cutting points A3 and A4 by the FIB processing. Next, the connection wiring L2 is newly formed so as to be connected to the connection point B3 of the top layer connection wiring of the wiring cell FP3 and the connection point B4 of the top layer connection wiring of the wiring cell FP5.

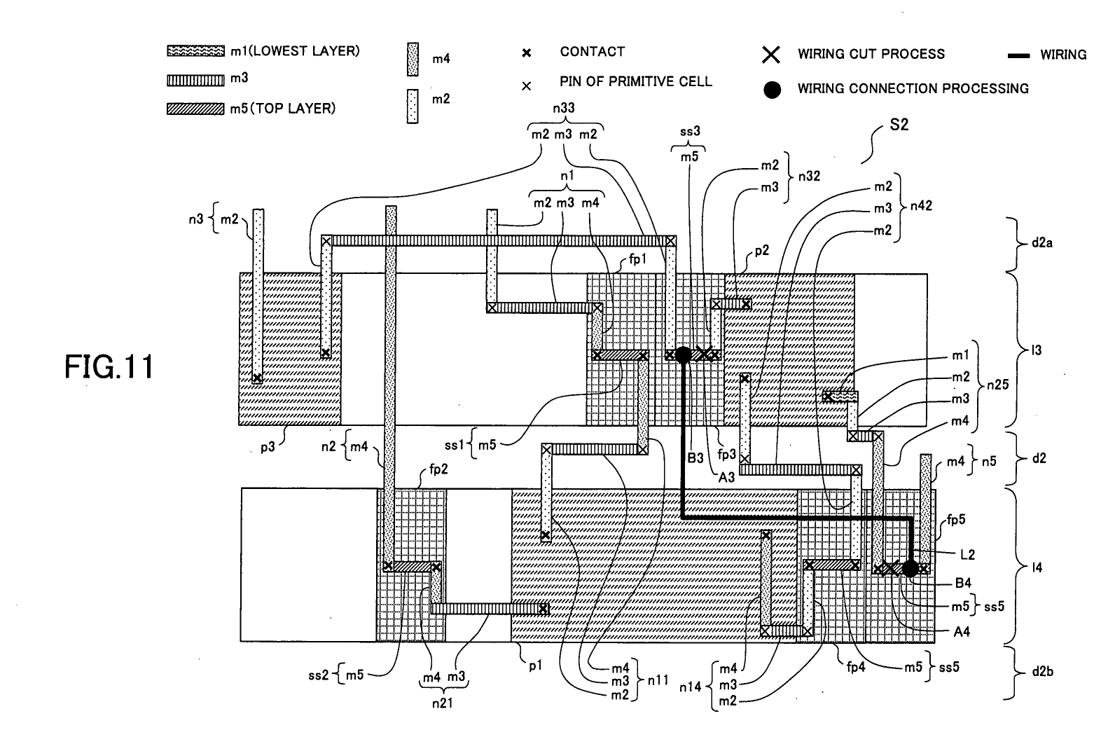

FIG. 11 is a plan view of the semiconductor device in a correction state shown in the circuit diagram of FIG. 10. In FIG. 11, parts that are the same as the parts already discussed above are given the same reference numerals, and explanation thereof is omitted.

Referring to FIG. 11, in the correction of the circuit in this embodiment, the top layer connection wiring ss3 of the wiring cell fp3 and the top layer connection wiring ss5 of the wiring cell fp5 are cut and a wiring is connected to the vicinity of the cutting points.

More specifically, first, the cutting points A3 of the top layer connection wiring ss3 and A4 of the top layer connection wiring ss5 are cut by the FIB processing. Then, for example, a contact is formed at each of the connection points B3 and B4 in the vicinity of the cutting points A3 and A4, respectively. The wiring L2 connected to the contacts and made of a metal such as W (tungsten) is formed so that the connection points B3 and B4 are connected. In this case, the contact pierces a protection film such as SiN which covers the top layer wiring and the wiring L2 is formed on the protection film.

Thus, in the semiconductor device of this embodiment, the circuit can be corrected by correcting the top layer wiring. Therefore, the upper layer of the wiring which is a subject of the correction is not covered with other wiring at the time of FIB processing and therefore it is possible to achieve a high pressing ability. More specifically, it is possible to easily find the wiring which is subject of the processing and to easily cut the wiring in a short period of time by spattering in the case of the FIB processing.

Although FIG. 9 through FIG. 11 describe a connection wiring which connects the primitive cells, other various multilayer wiring are actually formed.

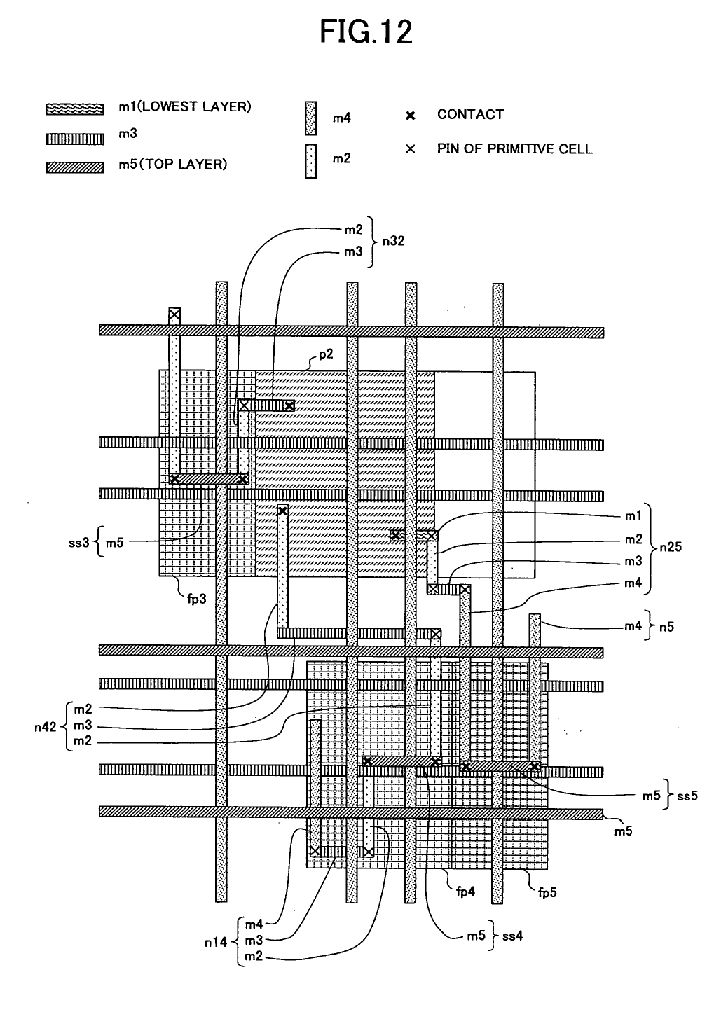

FIG. 12 is a schematic plan view showing details of an arrangement of the semiconductor device of the first embodiment of the present invention. In FIG. 12, parts that are the same as the parts already discussed above are given the same reference numerals, and explanation thereof is omitted.

In FIG. 9, although the connection wirings which connect the primitive cells and the top layer connection wiring are shown, other wirings are omitted. However, as shown in FIG. 12, various multi wirings are actually formed in the primitive cells. For example, since the top layer connection wirings ss3 and ss5 which are subjects of the FIB processing are formed by the top layer wiring m5 in the correcting process shown in FIG. 10 and FIG. 11, the top layer connection wirings ss3 and ss5 are not covered with the upper layer so that the correction processing can be easily done.

Various wirings other than the wiring connected to the top layer connection wiring are formed in the wiring cells fp3 through fp5. Thus, the wiring cell can be used as an area for forming other wirings. For example, the wirings m4, m3 and m2 which are lower layer wirings of the wiring m5 are formed in the wiring cell fp3. The wirings m4 and m3 which are lower layer wirings of the wiring m5 is formed in the wiring cell fp5. Such a lower layer wiring can be optionally formed in the wiring cell regardless of a configuration of the top layer connection wiring.

It is possible to form the wiring m5 which is a top layer wiring by such a wiring. The wiring m5, other than the top layer connection wiring ss5, is formed in the wiring cell fp5. Thus, the wiring is arranged without interfering with the top layer connection wiring so that the wiring can be formed in the top layer of the wiring cell.

It is possible to control the density of the wirings formed in the areas d2, d2a and d2b shown in FIG. 9, for example, by using the wiring cell as a wiring area.

In the related art semiconductor device having a high integration and a microstructure, an area where such a wiring is formed, namely a space such as the area d2, d2a or d2b is lacking, and therefore it is difficult to arrange the wiring.

However, in this embodiment, since the wiring cell is formed as the area where the wiring is to be formed, it is possible to control the density of the wiring formed surrounding the primitive cell so that the integrated circuit of the semiconductor device can have a high density and a microstructure. Therefore, it is possible to form a semiconductor device having high performance.

The present invention is not limited to the above-discussed embodiments, but variations and modifications may be made without departing from the scope of the present invention.

For example, although the top layer connection wiring, the connection wiring and other wirings discussed in this embodiment can be made of a metal such as Al, Cu or W, the present invention is not limited to this. Various conductive materials may be used. In addition, a barrier film or an adhesion film of the wiring may be added, if necessary.

Various methods such as a spattering method, CVD method, or plating method may be used as a method for forming the wiring.

In addition, although a five-layer wiring structure is used in this embodiment as an example of the multilayer wiring structure, the present invention is not limited to this. For example, the present invention can be applied to a case where the number of layers is greater than five (six-layers, seven-layers, eight-layers) or a case where the number of layers is less than five (four-layers, three-layers). In this case, the same effect as the effect achieved by the above-discussed embodiment can be achieved.

This patent application is based on Japanese Priority Patent Application No. 2004-186527 filed on Jun. 24, 2004, the entire contents of which are hereby incorporated by reference.

1. A semiconductor device, comprising:
a plurality of primitive cells having multilayer wiring structures and formed on a substrate;
wherein the primitive cell includes a functional cell having a logic circuit and a wiring cell,
the wiring cell includes a wiring part electrically connecting a plurality of the functional cells, and
the wiring part is a top layer connection wiring formed by a top layer wiring of the multilayer wiring structure.

2. The semiconductor device as claimed in claim 1,
wherein a lower layer wiring is formed in a lower layer of the wiring cell lower than the top layer connection wiring.

3. The semiconductor device as claimed in claim 2,
wherein the wiring cell is connected from the lower layer wiring to the top layer connection wiring.

4. The semiconductor device as claimed in claim 3,
wherein the lower layer wiring is formed in the functional cell, and
the functional cell is connected to the top layer connection wiring via the lower layer wiring.

5. The semiconductor device as claimed in claim 1,
wherein the functional cell and the wiring cell are arranged in a straight line so as to form a primitive cell line, and
a plurality of the primitive cells are formed in parallel.

6. The semiconductor device as claimed in claim 1,
wherein a wiring structure including the wiring part is formed in the wiring cell.

7. A manufacturing method of a semiconductor device having a multilayer wiring structure, comprising the steps of:
arranging primitive cells wherein a circuit is defined and designing a connection circuit connecting the primitive cells; and
forming the primitive cells on a substrate based on the design;
wherein the primitive cell includes a functional cell having a logic circuit and a wiring cell having a wiring part electrically connecting a plurality of the functional cells, and
the wiring part includes a top layer connection wiring formed by a top layer wiring of the multilayer wiring structure.

8. The manufacturing method of the semiconductor device as claimed in claim 7,
wherein an input pin and an output pin of the wiring cell are formed on the top layer connection wiring.

9. The manufacturing method of the semiconductor device as claimed in claim 7,
wherein the connection circuit includes a circuit connecting a plurality of the functional cells via the wiring cell.

10. The manufacturing method of the semiconductor device as claimed in claim 7,
wherein the wiring part defined in the wiring cell includes only the top layer wiring.

11. The manufacturing method of the semiconductor device as claimed in claim 7,
wherein a lower layer wiring formed in a layer lower than the top layer wiring is defined in the functional cell.

12. The manufacturing method of the semiconductor device as claimed in claim 11,
wherein the connection circuit includes a circuit connecting the lower layer wiring formed in the functional cell and the top layer connection wiring.

13. The manufacturing method of the semiconductor device as claimed in claim 7, further comprising the steps of:
testing an operation of an integrated circuit formed by the primitive cells; and
correcting a circuit of the primitive cell, corresponding to the result of testing the operation.

14. The manufacturing method of the semiconductor device as claimed in claim 13,
wherein the circuit is corrected by correcting the top layer connection wiring.

15. The manufacturing method of the semiconductor device as claimed in claim 13,
wherein the top layer connection wiring is cut so that the circuit is corrected.

16. The manufacturing method of the semiconductor device as claimed in claim 15,
wherein the top layer connection wiring is cut by a focused ion beam.

17. The manufacturing method of the semiconductor device as claimed in claim 7,
wherein the functional cell and the wiring cell are arranged in a straight line so as to form a primitive cell line, and
a plurality of the primitive cells are formed in parallel.

18. A design method of a semiconductor device having a multilayer wiring structure, comprising the steps of:
arranging primitive cells wherein a circuit is defined and designing a connection circuit connecting the primitive cells; and
forming the primitive cells on a substrate based on the design;
wherein the primitive cell includes a functional cell having a logic circuit and a wiring cell having a wiring part electrically connecting a plurality of the functional cells, and
the wiring part includes a top layer connection wiring formed by a top layer wiring of the multilayer wiring structure.

19. The design method of a semiconductor device as claimed in claim 18,
wherein an input pin and an output pin of the wiring cell are formed on the top layer connection wiring.

20. The design method of a semiconductor device as claimed in claim 18,
wherein the connection circuit includes a circuit connecting a plurality of the functional cells via the wiring cell.

21. The design method of a semiconductor device as claimed in claim 18,
wherein the wiring part defined in the wiring cell includes the only top layer wiring.

22. The design method of a semiconductor device as claimed in claim 18,
wherein a lower layer wiring formed in a layer lower than the top layer wiring is defined in the functional cell.

23. The design method of a semiconductor device as claimed in claim 22,
wherein the connection circuit includes a circuit connecting the lower layer wiring formed in the functional cell and the top layer connection wiring.
